(19) United States
(12) Patent Application Publication
(10) Pub. No.: US 2012/0155175 A1
(43) Pub. Date: Jun. 21, 2012

(54) FLASH MEMORY DEVICE AND OPERATION METHOD THEREOF

(76) Inventor: Won-Kyung KANG, Gyeonggi-do (KR)

(21) Appl. No.: 13/111,686

(22) Filed: May 19, 2011

(30) Foreign Application Priority Data
Dec. 17, 2010 (KR) 10-2010-0129698

(51) Int. Cl. G11C 16/04

(52) U.S. Cl. 365/185.11

(57) ABSTRACT

A method for operating a flash memory device includes storing a first command and a first address corresponding to a first plane, storing a second command and a second address corresponding to a second plane, and performing a first command operation for the first plane based on the first command and the first address and performing a second command operation for the second plane based on the second command and the second address, wherein the first address includes a first block address for selecting a block in the first plane, and the second address includes a second block address for selecting a block in the second plane.

### CROSS-REFERENCE TO RELATED APPLICATIONS

The present application claims priority of Korean Patent Application No. 10-2010-0129698, filed on Dec. 17, 2010, which is incorporated herein by reference in its entirety.

### BACKGROUND

1. Field

Exemplary embodiments of the present invention relate to a flash memory device for performing a multi-plane operation, and a method for operating the flash memory device.

2. Description of the Related Art

Semiconductor memory devices may be classified into a volatile memory device and a non-volatile memory device depending on whether data are retained or not when a power supply is cut off. Flash memory devices belong to the category of non-volatile memory devices. A flash memory device carries both of the advantage of Random Access Memory (RAM), in which data are stored and erased freely, and the advantage of Read Only Memory (ROM), in which data stored therein are retained even though a power supply is cut off. For this reason, flash memory devices are widely used as storage media for many digital devices, such as Personal Digital Assistant (PDA), smart phone, and digital camera.

Differently from other memory devices, flash memory devices perform a process of electrically erasing and re-storing data of a predetermined unit of memory cells to change the data that have been stored before. In other words, when a data is stored in a memory cell in the initial state and the data is to be changed, a predetermined number of memory cells including the memory cell should be re-initialized through an electrical erase process and then a changed data is re-stored. The unit of memory cells that are electrically erased at one time is referred to as a block, and the unit of memory cells that may be programmed with a data, that is, the unit of memory cells where a data is stored, is referred to as a page. For example, one block may include 32 or 64 pages.

While all the blocks of a flash memory device have been disposed over a single plane, blocks may be evenly distributed over more than two planes. Therefore, one block or page may be selected for each plane and an electrical erase operation or a program/read operation may be simultaneously performed for the selected blocks or pages. This is referred to as a multi-plane operation.

In a conventional flash memory device, the multi-plane operation may be performed only on the blocks of the same block address in multiple planes. Therefore, if a bad block occurs in one plane only, the multi-plane operation may not be performed for the corresponding block address. The counterpart blocks of the other planes are to be treated as bad blocks or the multi-plane operation is to be converted into a single plane operation. This may deteriorate the overall performance of the flash memory device and increase the number of virtual bad blocks, which leads to reduction in the life-span of the flash memory device.

### SUMMARY

An embodiment of the present invention is directed to a flash memory device which may perform a multi-plane operation for blocks of different block addresses, and a method for operating the flash memory device.

In accordance with an embodiment of the present invention, a method for operating a flash memory device includes: storing a first command and a first address corresponding to a first plane; storing a second command and a second address corresponding to a second plane; and performing a first command operation for the first plane based on the first command and the first address and performing a second command operation for the second plane based on the second command and the second address, wherein the first address includes a first block address for selecting a block in the first plane, and the second address includes a second block address for selecting a block in the second plane.

In accordance with yet another embodiment of the present invention, a flash memory device includes: a first plane and a second plane each including a plurality of memory blocks; a command controller configured to store a first command and a second command corresponding to the first plane and the second plane, respectively; and an address controller configured to store at least one address applied to the first plane and the second plane in common and store first and second block addresses for selecting a block in the first and second planes, respectively.

In accordance with another embodiment of the present invention, a method for operating a flash memory device comprising a plurality of groups of blocks includes: storing a plurality of block addresses for a block of the respective groups; and simultaneously performing an operation corresponding to input commands for the respective blocks in response to the input commands and the block addresses.

### BRIEF DESCRIPTION OF THE DRAWINGS

FIG. 1A is a flowchart describing a method for operating a flash memory device in accordance with an embodiment of the present invention.

FIG. 1B is a flowchart describing a method for performing a program operation of a flash memory device in accordance with an embodiment of the present invention.

FIG. 2 is a block diagram illustrating a flash memory device in accordance with an embodiment of the present invention.

FIG. 3 is a timing diagram of a program operation performed in the flash memory device of FIG. 2.

FIG. 4 illustrates a multi-plane operation for blocks of different block addresses in the flash memory device of FIG. 2.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

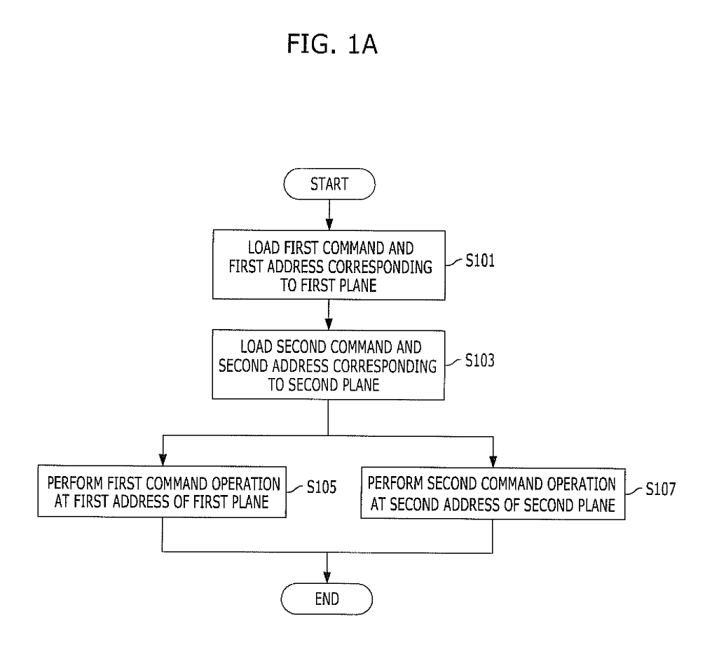

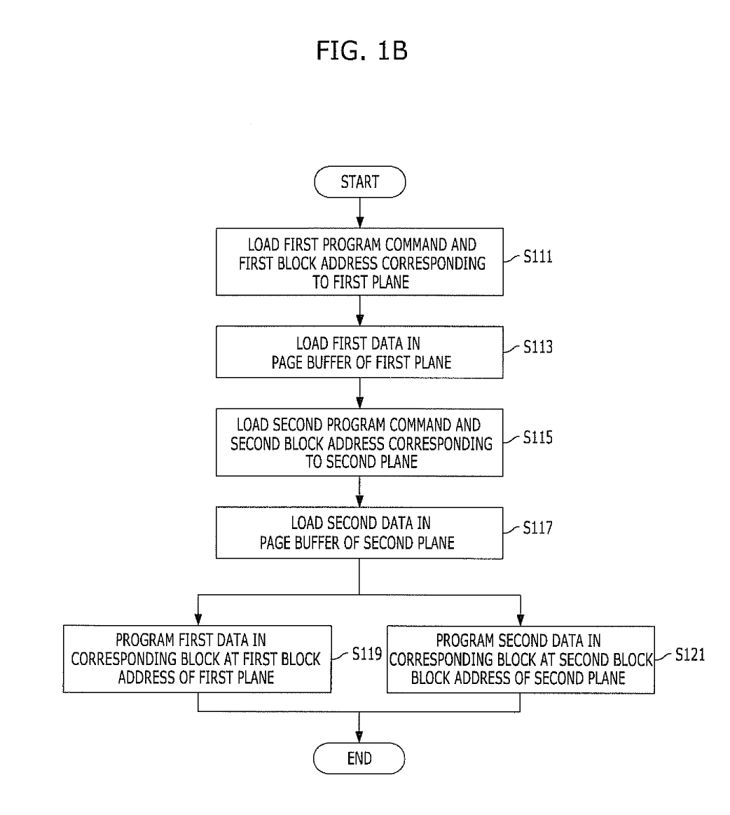

FIG. 1A is a flowchart describing a method for operating a flash memory device in accordance with an embodiment of the present invention. FIG. 18 is a flowchart describing a method for performing a program operation of a flash memory device in accordance with an embodiment of the present invention.

Referring to FIG. 1A, the method for operating a flash memory device in accordance with the embodiment of the present invention includes: loading a first command and a first address corresponding to a first plane in step S101; loading a second command and a second address corresponding to a second plane in step S103; performing a first command operation in the first address of the first plane in step S105; and performing a second command operation in the second address of the second plane in step S107. The first command operation performing step S105 and the second command operation performing step S107 may be performed simultaneously.

Here, the first command and the second command are a set of commands of the same kind, and the first command and the second command may make the same operation performed in the first plane and the second plane.

Also, the first address includes a first block address for selecting a block in the first plane, while the second address includes a second block address for selecting a block in the second plane.

Referring to FIG. 1B, a method for performing a program operation of a flash memory device in accordance with the embodiment of the present invention includes: loading a first program command and a first block address corresponding to a first plane in step S111; loading a first data in a page buffer of the first plane in step S113; loading a second program command and a second block address corresponding to a second plane in step S115; loading a second data in a page buffer of the second plane in step S117; programming the first data in a block corresponding to the first block address in the first plane in step S119; and programming the second data in a block corresponding to the second block address in the second plane in step S121. The first data programming step S119 and the second data programming step S121 may be performed simultaneously.

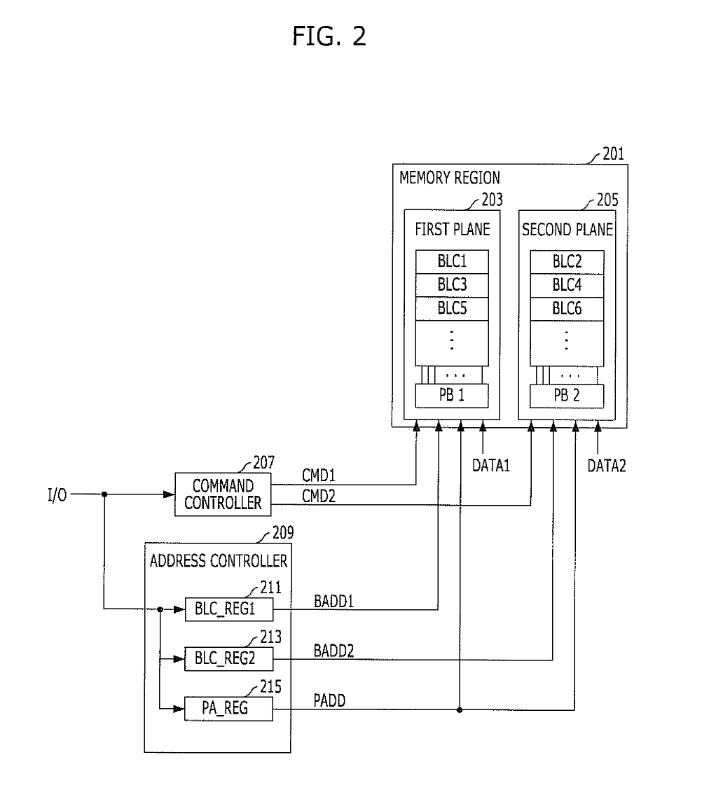

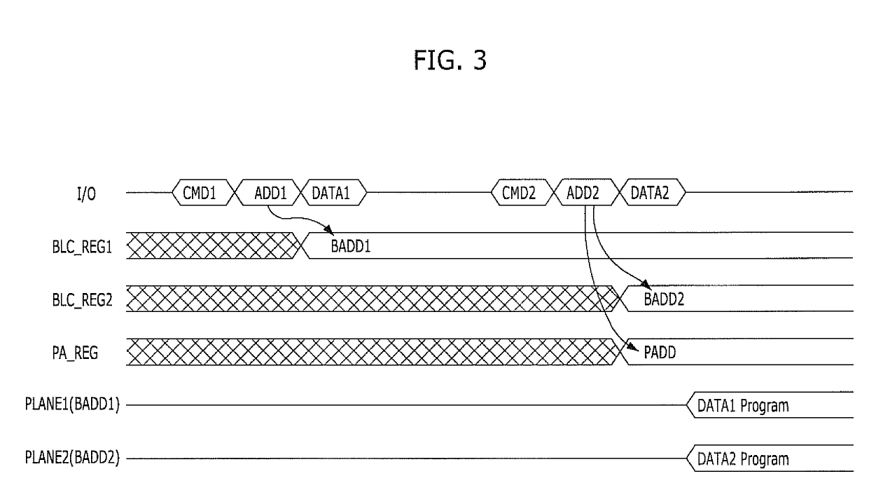

In this embodiment of the present invention, since the first block address and the second block address may be different, a multi-plane operation may be performed for blocks of different block addresses. Hereafter, this is described with reference to FIGS. 2 and 3.

FIG. 2 is a block diagram illustrating a flash memory device in accordance with an embodiment of the present invention.

Referring to FIG. 2, the flash memory device includes a memory region 201, a command controller 207, and an address controller 209. The memory region 201 includes a first plane 203 and a second plane 205. The command controller 207 supplies a first command CMD1 and a second command CMD2 to the first plane 203 and the second plane 205, respectively. The address controller 209 supplies one or more addresses BADD1, BADD2 and PADD to the first plane 203 and the second plane 205, respectively, or in common.

The address controller 209 includes a first block address storage 211, a second block address storage 213, and a page address storage 215. The first block address storage 211 loads a first block address BADD1 for selecting a block in the first plane 203. The second block address storage 213 loads a second block address BADD2 for selecting a block in the second plane 205. The page address storage 215 selects a page in a block.

The first plane 203 and the second plane 205 in the memory region 201 includes a plurality of blocks BLC1, 3, 5, . . . , BLC 2, 4, 6, . . . and page buffers PB1 and PB2, and each block includes a plurality of pages. Here, a pair of blocks positioned at the same line of the first plane 203 and the second plane 205 may have the same block address. In other words, a pair of a first block BLC1 and a second block BLC2 and a pair of a third block BLC3 and a fourth block BLC4 are positioned on the same block address individually. The page buffers PB1 and PB2 temporarily stores data DATA1 and DATA2 that are inputted/outputted during a program operation or a read operation.

The command controller 207 loads the first command CMD1 and the second command CMD2 for a multi-plane operation. The first command CMD1 and the second command CMD2 correspond to the first plane 203 and the second plane 205, respectively, and they are a set of commands of the same kind that makes the same operation performed in the first plane 203 and the second plane 205. That is, the same operation may be performed simultaneously in the first plane 203 and the second plane 205 in response to the first command CMD1 and the second command CMD2, respectively.

In a flash memory device, a different address is used depending on the kind of an operation. For example, an erase operation is performed on a block basis, and thus a block address may be used. On the other hand, a program operation or a read operation is performed on a page basis. Therefore, a block address and a page address are inputted together.

Therefore, the address controller 209 separately stores a block address and a page address from the address information inputted through an input/output pad (I/O) and applies an address to be used to the memory region in response to a command. When a block address is stored in the address controller 209 each time, the multi-plane operation may be performed for the blocks of the one block address. According to an embodiment of the present invention, however, the address controller 209 may be provided with one or more block address storages, for example, two block address storages 211 and 213 therein, and each block address storage may store a different block address BADD1 or BADD2. Therefore, the multi-plane operation may be performed for blocks of different block addresses.

The operations of the first block address storage 211 and the second block address storage 213 may be controlled by an inputted command. For example, in a duration where the first command CMD1 is inputted, the first block address storage 211 is operated to store the first block address BADD1. On the other hand, in a duration where the second command CMD2 is inputted, the second block address storage 213 is operated to store the second block address BADD2.

The first block address storage 211 and the second block address storage 213 may store different block addresses in another manner as follows. First, the first block address storage 211 stores the first block address BADD1 that is inputted first and then the first block address storage 211 may be disabled from storing a subsequent address inputted thereto in response to the second command CMD2. The second block address storage 213 may store a newly inputted block address whenever a block address is inputted. Therefore, eventually, the first block address storage 211 stores the first block address BADD1 corresponding to the first plane 203, and the second block address storage 213 stores the second block address BADD2 corresponding to the second plane 205.

The latter method may simplify the circuit structure of the address controller 209 more than the former method. Therefore, the area of a memory device may be reduced more.

FIG. 3 is a timing diagram of a program operation performed in the flash memory device of FIG. 2.

First, the first command CMD1, the first address ADD1, and the first data DATA1 which correspond to the first plane 203 are inputted through an input/output pad I/O, and then the second command CMD2, the second address ADD2, and the second data DATA2 which correspond to the second plane 205 are inputted through the input/output pad I/O. The first command CMD1 and the second command CMD2 may be a set of commands for performing a program operation. The first address ADD1 includes a first block address BADD1 and the second address ADD2 includes a second block address BADD2 and a page address PADD.

The first block address storage BLC_REG1 loads/stores the first block address BADD1 included in the first address ADD1, and the second block address storage BLC_REG2 loads/stores the second block address BADD2 included in the second address ADD2. The first block address BADD1 and the second block address BADD2 may be different. Therefore, the multi-plane operation may be performed for the blocks of different block addresses of the first plane 203 and the second plane 205.

The page address storage PA_REG loads/stores the page address PADD included in the second address ADD2. Since one page address PADD is loaded differently from the first block address BADD1 and the second block address BADD2, the multi-plane operation is performed onto the same page address in each block. The page address PADD may be included in the first address ADD1 instead of the second address ADD2.

The first data DATA1 and the second data DATA2 are loaded onto the first page buffer PB1 and the second page buffer PB2 of the first plane 203 and the second plane 205, respectively, and programmed in a page of each block selected by the loaded first and second block addresses BADD1 and BADD2 and the page address PADD.

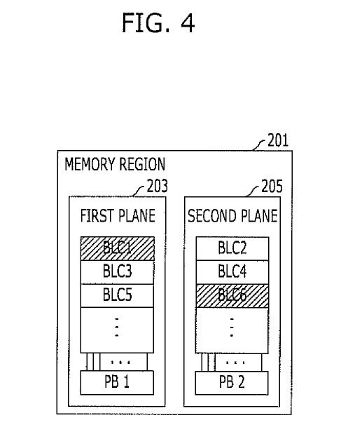

FIG. 4 illustrates a multi-plane operation for blocks of different block addresses in the flash memory device of FIG. 2.

Referring to FIG. 4, when the first block address BADD1 corresponds to the first block BLC1 and the second block address BADD2 corresponds to the sixth block BLC6, the multi-plane operation may be performed simultaneously in the two blocks having different block addresses, which are the first block BLC1 and the sixth block BLC6. In this way, the operation performance of the flash memory device may be increased, and the number of virtual bad blocks may be prevented from being increased and thus the life-span of the flash memory device may be also prevented from being shortened.

Although the technology of the present invention is described by taking an example of a flash memory device having two planes, the same may be applied to a flash memory device having more than two planes. For example, when a memory region includes four planes, an address controller may have four block address storages and store different block addresses in the fourth block address storages, respectively, so as to perform a multi-plane operation for the blocks of four different block addresses.

According to an embodiment of the present invention, the multi-plane operation may be performed for blocks of different block addresses by separately loading and storing block addresses corresponding to multiple planes, respectively, and the performance of a flash memory device may be increased through the multi-plane operation.

Also, although a bad block occurs in one plane while a flash memory device is used, the counterpart blocks of the other planes which have the same block address as the bad block may not be considered as bad blocks. In this way, the number of virtual bad blocks is prevented from being increased and thus the life-span of the flash memory device is prevented from being decreased.

While the present invention has been described with respect to the specific embodiments, it will be apparent to those skilled in the art that various changes and modifications may be made without departing from the spirit and scope of the invention as defined in the following claims.

What is claimed is:

1. A method for operating a flash memory device, comprising:
storing a first command and a first address corresponding to a first plane;
storing a second command and a second address corresponding to a second plane; and
performing a first command operation for the first plane based on the first command and the first address and performing a second command operation for the second plane based on the second command and the second address,
wherein the first address comprises a first block address for selecting a block in the first plane and the second address comprises a second block address for selecting a block in the second plane.

2. The method of claim 1, wherein the first block address and the second block address are different from each other.

3. The method of claim 1, wherein the first command operation and the second command operation are performed in response to the first and second commands, respectively, and are each the same operation in the first plane and the second.

4. The method of claim 3, wherein the first command operation and the second command operation are simultaneously performed in the first plane and the second plane.

5. The method of claim 1, further comprising:
storing a first data in a page buffer of the first plane; and
storing a second data in a page buffer of the second plane,
wherein the first and second commands include a program command.

6. The method of claim 5, wherein the first command operation is performed by programming the first data in the selected block of the first plane and the second command operation is performed by programming the second data in the selected block of the second plane.

7. A flash memory device, comprising:
a first plane and a second plane each comprising a plurality of memory blocks;
a command controller configured to store a first command and a second command corresponding to the first plane and the second plane, respectively; and
an address controller configured to store at least one address applied to the first plane and the second plane in common and store first and second block addresses for selecting a block in the first and second planes, respectively.

8. The flash memory device of claim 7, wherein the address controller comprises:
a first block address storage configured to store the first block address;
a second block address storage configured to store the second block address; and
a page address storage configured to store at least said one address.

9. The flash memory device of claim 8, wherein the first block address and the second block address are different from each other.

10. The flash memory device of claim 9, wherein the first block address and the second block address are sequentially stored in the address controller.

11. The flash memory device of claim 10, wherein the second block address storage is configured to store the first block address first and store the second block address inputted subsequently by replacing the first block address.

12. The flash memory device of claim 10, wherein the first block address storage is disabled in storing data in response to the second command, after storing the first block address, and
the second block address storage is configured to store the second block address in response to the second command.

13. The flash memory device of claim 8, wherein the first command and the second command are a set of commands for performing the same operation in the first plane and the second plane, respectively.

14. The flash memory device of claim 13, wherein the same operation is performed simultaneously in the first plane and in the second plane.

15. A method for operating a flash memory device comprising a plurality of groups of blocks, comprising:
storing a plurality of block addresses for a block of the respective groups; and
simultaneously performing an operation corresponding to input commands for the respective blocks in response to the input commands and the block addresses.

16. The method of claim 15, wherein the plurality of block addresses are different from each other and sequentially stored, and the block addresses correspond to the respective blocks.
